(19) United States
(12) Patent Application Publication
(10) Pub. No.: US 2009/0181185 A1
(43) Pub. Date: Jul. 16, 2009

(54) METHOD AND APPARATUS FOR SURFACE TREATMENT OF CONTAINERS OR OBJECTS

(76) Inventors: Stefan Grosse, Gerlingen (DE); Johannes Rauschnabel, Ilshofen-Eckartshausen (DE); Jochen Feichtinger, Ilsfeld-Helfenberg (DE); Carsten Herweg, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/302,594

(22) PCT Filed: Mar. 26, 2007
(86) PCT No.: PCT/EP07/52886

§ 371 Date: Nov. 26, 2008

(30) Foreign Application Priority Data
May 26, 2006 (DE) 10 2006 024 675.6

(51) Int. Cl. H05H 1/24; C23C 16/54

(52) U.S. Cl. 427/569; 118/723 R; 118/723 MP

(57) ABSTRACT

The invention relates to a method and a device for treating the surfaces of containers or objects in which the inner surfaces to be treated are exposed to functionalizing plasma during a process step, and/or to coating plasma during a further process step. The functionalizing plasma and the coating plasma are preferably produced by a plasma source which is located inside or outside the containers or objects.

### PRIOR ART

The invention relates to a method and an apparatus for surface treatment of containers or objects, in particular in pharmaceutical packages, such as vials, injection kits or carpules, as generically defined by the preamble to claim 1.

It is widely known that to improve the slidability of closure stoppers in pharmaceutical packages, or when evacuating ready-made syringes or cylindrical ampules for injections, so-called firing on the affected surface of the pharmaceutical package is provided for. In the case of injection bottles as well, so-called vials, siliconizing can be done in the interior, to enable complete evacuation.

Typically, this siliconizing process is done, for instance with bulk syringes or bulk carpules, in such a way that after nonsterile syringes or carpules are furnished in bulk, cleaning is done in the washing machine, and in the final station of the washing machine, a defined quantity of silicone oil is injected into the syringe or carpule. The next station is typically a heating tunnel, through which the syringes or carpules are pushed in bulk; the heat assures the necessary sterility and simultaneously serves to fire the siliconization. The sterile, siliconized syringes and carpules are then filled.

In the case of presterilized syringes in the nest, so-called SCF™ syringes (SCF™=Sterile Clean Fill), the syringes are cleaned in a bulk cleaning machine before the sterilization, and in the last station of the washing machine they are provided with a defined quantity of silicone oil. Next, the syringes are packaged and sent for sterilization with ethylene oxide, so that shipment of sterile syringes with siliconization can be done in so-called SCF tubs. Alternatively, here as well, the siliconization can also be fired in a heating tunnel. In both of the above cases, however, the processing steps are outsourced to the manufacturer of the packaging means.

This known pyrosiliconization is often done, despite some disadvantages, in order to assure the easy sliding of stoppers or substances in the package. This easy sliding is necessary so that for instance upon injection, the medication can be administered to the patient continuously without pressure surges. However, particularly in pharmaceutical packages, such as injection kits or the like, is disadvantageous if for no other reason already because of the risk that upon injection, some of the siliconization will be injected into the patient as well. Moreover, the reaction of ingredients in the medication with the siliconization lessens the storage capability of some pharmaceutical products.

From German Patent Disclosure DE 199 03 935 A1, a method for sterilizing containers or objects is known per se in which a plasma is excited in or on the containers or objects by means of electromagnetic vibrations. Such a method is also known as the plasma sterilization process, or here for short as the plasma process.

### DISCLOSURE OF THE INVENTION

According to the invention, in a method for surface treatment of containers or objects, the inner surfaces to be treated are advantageously treated in a plasma process in such a way that an improvement in the slidability is obtained, in particular by means of a coating. Preferably, the inner surfaces to be treated are exposed in one method step to a functionalizing plasma, that is, to a plasma that improves the wetting capability of the surface or that cleans it, and in another method step to a coating plasma. Advantageously, the functionalizing plasma and the coating plasma are generated by the same plasma source, which is disposed inside or outside the surfaces of pharmaceutical packages or objects.

In principle, a distinction can be made among a number of types of plasma excitation. The plasma can be generated for instance directly in the pharmaceutical package; by means of a suitable arrangement, a high field intensity in the interior of the pharmaceutical package is generated, so that a plasma ignites there. However, the plasma can also be generated by a microplasma source and forced into the pharmaceutical package. The energy for the ionization in the microplasma source can be selectively an inductive or capacitive high-frequency inputting or a microwave inputting. So-called remote plasma generation can also be done, in which the plasma is generated outside the pharmaceutical package and expands into the pharmaceutical package or is intentionally drawn into the pharmaceutical package by an air flow.

According to the invention, the functionalizing plasma is generated with a first working gas, and the coating plasma is made with a second working gas or fluid, at atmospheric pressure or at slight underpressure; the first working gas can for instance be argon, nitrogen, oxygen, hydrogen, or a combination of these gases.

In an advantageous embodiment of the invention, a non-coating plasma can be excited, with the remote plasma source disposed outside the object to be treated, and expands into the packaging means, or is pulled by an air flow. In this way—in an especially advantageous embodiment at the opening of the packaging means—a monomer for a coating plasma can be added. This arrangement helps to protect the plasma source itself against becoming coated.

The second working gas or working fluid is formed for instance of a silicon-containing monomer, such as hexamethyldisiloxane (HMDSO), tetraethoxysilane (TEOS), tetramethylsilane (TMS), or oxygen, or a combination of these substances, for a deposition of silicon oxide (SiOₓ) layers. The second working gas or working fluid can also be formed of a carbon-containing monomer, such as methane, acetylene, or halogenated hydrocarbons, or a combination of these substances, for a deposition of carbon layers on the surface to be treated. It is possible in principle also to employ liquid precursors for the coating. For instance, the substance known as HMDSO is available in liquid form.

The two method steps can also be repeated as often as desired, to attain an improvement in the outcome. It is moreover also conceivable to perform the method steps, in certain applications, independently of one another as a single-step process. It is also conceivable for the functionalizing method step to be done immediately following the coating method step, to obtain a further improvement of the surface.

Thus by the use of a single plasma source, the present invention makes it possible to replace the pyrosiliconization mentioned at the outset with an advantageously performed internal coating as a plasma-polymerized sliding layer, or by means of a plasma-induced modification of the inside of the container or object.

The plasma process can also be observed online with regard to the plasma density, for instance by way of the indirect parameter of light emission with the aid of a diode, and optionally readjusted as well. The coefficient of sliding friction on the surface can for instance be adjusted by way of the degree of cross-linking, that is, the performance of the plasma source and the pointwise dwell time during the plasma process in one or both method steps onto the applicable container, the type of stopper, and any other object.

The sliding layer generated according to the invention by the plasma is also advantageous because it is a great deal thinner, approximately <100 nm than the pyrosiliconization known from the prior art, which has a layer thickness of approximately 1-50 μm. The risk of layer separation in the invention is also markedly less, because of very much better adhesion, and thus the risk of contamination to the patient is reduced to a minimum.

By the application according to the invention of a sliding layer using a plasma source, it is thus possible to minimize the proportion of silicone in an injection kit because of the optimized polymerization with the plasma process, a targeted adaptation of the solid state sliding layer to the pharmaceutical product is possible.

The layer materials created can be selected in a simple way by means of the second working gas or fluid, examples being the quartzlike silicon oxide (SiOₓ) already mentioned or carbon, which, if they reach the blood circulation of the human, are medically much less objectionable than the known siliconization, and moreover, as a result of the treatment according to the invention, no unwanted interactions with the pharmaceutical products occur.

The method of the invention can additionally be employed for an especially economical and safe firing of a siliconization, in the event that such firing is not to be dispensed with; this use would be of advantage above all for packaging ready-made syringes comprising the aforementioned SCF tubs. The syringes can be taken directly out of the SCF tub and can be briefly treated with the plasma without a washing process or heating tunnel and then filled thereafter.

With an apparatus according to the invention for performing the method described above, an advantageous surface treatment can be done in the form of a coating, in particular of the inner surface of a container or object, using a plasma source that is present inside or outside the container or object during the first and the second method steps. Means are also present for feeding in the first and the second working gas.

It is especially advantageous here if the plasma source is an arrangement for generating high-frequency vibration, of the kind described per se in the prior art, DE 199 03 935 A1, mentioned at the outset. In a first embodiment, the plasma source is a microplasma source for inductive, capacitive, or microwave-based power inputting, which can optionally also be guided, in conjunction with an electron beam source, into the interior of the containers or objects to be treated.

By the use of the aforementioned microplasma, individual manipulation of the pharmaceutical package, known as single-piece flow, is easily possible.

A further advantage of the invention is the universal usability of the method and the apparatus for the most various packaging materials, in particular for plastics, which because of their thermal instability can be treated only to a limited extent in the heating tunnel. Since polymer packaging means, compared with packaging means of glass, have higher permeability to oxygen, which can lead to premature oxidation of the product, and since substances dissolved in the plastic, such as plasticizers, can migrate into the product, or an active ingredient can dissolve into the plastic, yet the use of the invention brings about a high degree of cross-linking of the coating or of the polymer surface, a longer shelf life or longer constancy of the effective dose of the product can be achieved. A variation in the coating thickness along the axis of the syringe is likewise easily possible by means of the invention; particularly in the region of the position of the elastomer stopper, a reliably closed layer is necessary during storage, to prevent ruptures in the layer.

In a second embodiment, the plasma source can be disposed outside the containers or objects to be treated; in a third embodiment, the plasma, in both method steps, can also be generated outside the containers or objects to be treated and can be introduced into one or more containers or objects by means of an arrangement for generating a gas flow.

Alternatively, it is also possible for an introduction of the container or object to be treated is effected into a precise-fit metal hollow body, which is subjected to a suitable voltage, either direct voltage or pulsed voltage. This for instance makes it possible to utilize a barrier discharge for the functionalizing cleaning and activation process or the plasma polymerization process according to the invention.

It is also advantageously possible for the plasma source to be coupled to a force measurement cell, for instance at the stopper placing station for the pharmaceutical container, in such a way that in the event of deviations from the set-point value for the force expenditure for forcing in the stoppers, the plasma source is readjusted in such a way that subsequent containers again display a friction resistance in the set-point range. This method cannot be employed in this way in the case of the known siliconization.

As already mentioned, it is also possible for only a partial coating or surface modification to be done, which either merely reduces the coefficient of adhesion, for instance at the seat of the stopper in the position of repose of a filled container, or also includes the sliding region. In the first instance, there would be no contact between the plasma polymer layer or modification region and the product. Such an advantage could hardly be attained with the conventional introduction of silicone, because of so-called overspray, or with pure vacuum plasma sources, because of the volume plasma. Here, the locally acting microdischarge source according to the invention that functions at or near atmospheric pressure has major advantages as the plasma source.

In conjunction with an electron beam source, an additional advantage can be attained, since the electron beam acts locally and, together with the plasma, can aid in intentionally modifying portions of the inside surface of the packaging means by for instance locally raising the degree of cross-linking. In an advantageous feature of this variant, structuring of the surface can also be achieved.

The invention will be described in further detail in terms of exemplary embodiments in conjunction with the drawings. In the drawings:

FIG. 1 is a schematic illustration of the generation of a first plasma in the interior of a syringe, as an example of use of a pharmaceutical object;

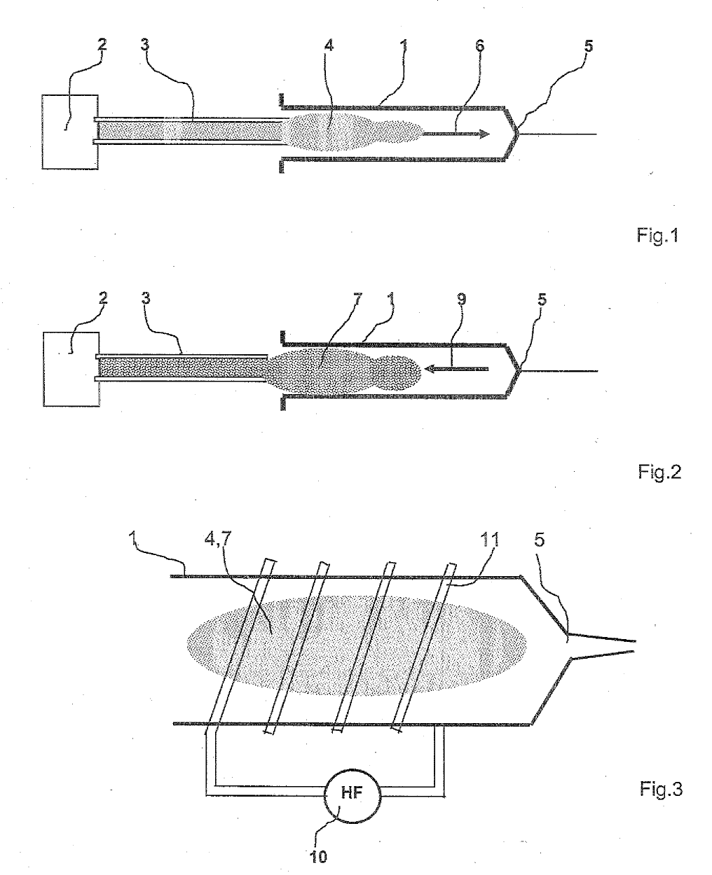

FIG. 2 is a schematic illustration of the generation of a second plasma in the interior of a syringe, for coating the inner surface of the syringe of FIG. 1;

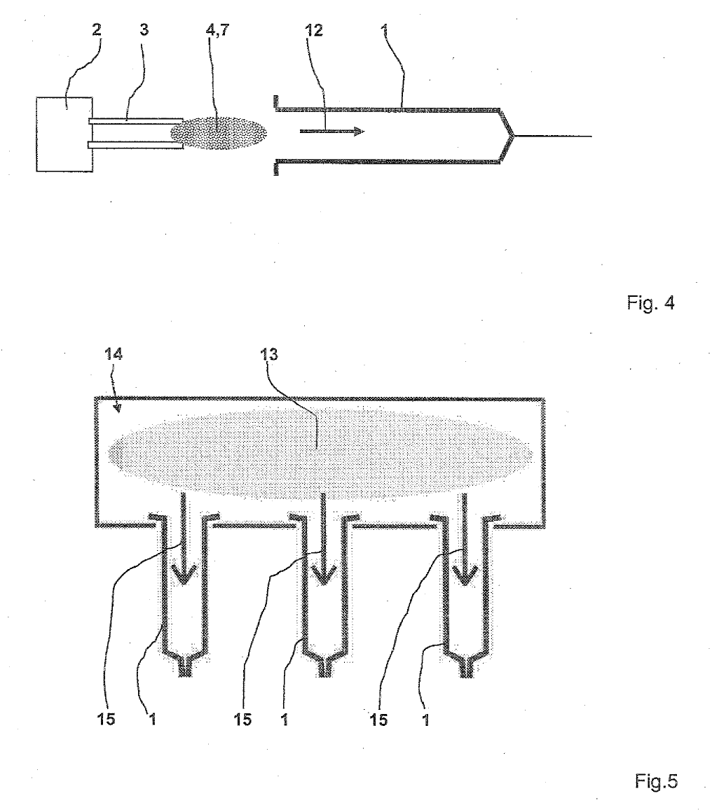

FIG. 3 shows an exemplary embodiment with an inductive plasma excitation outside the syringe of FIG. 1;

FIG. 4 shows an exemplary embodiment with the plasma excitation of the syringe and with an inflow of the plasma into the interior of the syringe of FIG. 1; and

FIG. 5 shows an exemplary embodiment with the plasma excitation outside a serial arrangement of syringes and with an inflow of the plasma into the interior of the syringes.

In FIG. 1, a syringe 1 is shown, as a pharmaceutical object to be treated on its inner surface. A plasma source 2 is also present, which here, with lancelike extensions 3, forms a so-called microplasma source, which carries a plasma 4, such as a microplasma, into the interior of the syringe 1 as a first method step for the cleaning and activation of the inner surface of the syringe 1, by the method known per se from the aforementioned prior art, DE 199 03 935 A1. From the lancelike extension 3 of the plasma source 2, the plasma 4 flows out, either at atmospheric pressure or optionally at a slight underpressure; the slight underpressure makes the purposeful pumping out of the waste gases easier.

The ignition of the plasma source 2 is effected with a non-coating first working gas, such as argon or oxygen, and with motion into the syringe 1, it generates the first plasma 4 in the direction of the syringe opening 5, as indicated by the arrow 6. This non-coating first plasma 4, upon its motion through the syringe 1, cleans the inner surface, later to be coated, of the syringe 1, thereby favorably affecting the adhesion of the layer to this surface.

Once the plasma source 1 has moved with its lancelike extension 3 all the way into the syringe 1, the working gas is switched over to a second, coating working gas in FIG. 2, for generating a second plasma 7. The second working gas may for instance comprise a silicon-containing monomer, such as HMDSO, TMS, TEOS, or oxygen, or combinations thereof for the deposition of SiOₓ layers, or it may comprise a carbon-containing monomer, such as methane, acetylene, or argon, or combinations thereof, for the deposition of carbon layers.

During the retraction of the lancelike extension 3 out of the syringe 1 of FIG. 2 in the direction of the arrow 9, the previously plasma-cleaned inner surface of the syringe 1 is coated with the coating working gas.

The invention, as already mentioned above, is applicable in principle to many known plasma sources that are capable of igniting a plasma 4 or 7 in the interior of the syringe 1 or other container or object. It is also possible for the lancelike extension 3 to be used only for introducing the working gases into the syringe 1. The plasma excitation can furthermore be realized by means of some other microwave-based power inputting as well.

FIG. 3 shows an exemplary embodiment with an inductive inputting of a high-frequency alternating field (from 1 kHz to 100 MHz), applied externally, by means of an HF generator 10 and a coil 11 into the syringe 1 for generating a plasma 4 or in an identical way for generating a plasma 7. However, here again, a capacitive, hollow-cathode or helicon high-frequency excitation or microwave excitation (1 to 10 GHz), which is conceivable for instance on the basis of the well-known Surfatron or Surfaguide or an in particular elliptical microwave concentrator.

In the exemplary embodiment of FIG. 4, the plasma 4, 7 is likewise generated by a plasma source 2 and is forced into the syringe 1 by an air flow as indicated by the arrow 12. The energy for the ionization in the plasma source 2 can, as already mentioned above, selectively be an inductive or capacitive high-frequency inputting or a microwave inputting.

From FIG. 5, a further exemplary embodiment can be seen, in which a so-called remote plasma 13 is generated. Here, the plasma 13 is generated outside a series of syringes 1, as pharmaceutical packages, in an apparatus 14, and it expands into the syringes 1 as indicated by the arrow 15 or is purposefully drawn into the syringes 1 by a suitable air flow.

The exemplary embodiments shown and described represent only a selection for many variants for selecting the working gases or fluids and for the sequence of the process. It is also possible for many coating gases or substances to be used as the second working gas or fluid, and all silicon-containing monomers or carbon-containing monomers, or coatings that contain silicon and carbon are especially advantageous. A multilayer comprising the aforementioned layer systems can selectively be employed as well.

The sequence, shown in conjunction with the drawings, of the cleaning or functionalizing as the syringes move inward and their coating as they move outward is only one advantageous possibility of the course of the process for the plasma sources of the microplasma source type; still other courses of the process or repetitions are also conceivable.

1-15. (canceled)

16. A method for surface treatment, especially in the interior of containers or objects, comprising the step of exposing any surfaces to be treated at least once to a functionalizing plasma and/or to a coating plasma.

17. The method as defined by claim 16, wherein the surfaces to be treated are exposed in one method step to the functionalizing plasma, preferably a plasma that cleans and/or enhances the wetting capability, and/or, in a further process-coupled method step, to the coating plasma.

18. The method as defined by claim 16, further comprising the step of generating the functionalizing plasma and the coating plasma by a same plasma source, which is disposed inside or outside the containers or objects.

19. The method as defined by claim 17, further comprising the step of generating the functionalizing plasma and the coating plasma by a same plasma source, which is disposed inside or outside the containers or objects.

20. The method as defined by claim 16, wherein the functionalizing plasma is effected with a first working gas, and the coating plasma is made with a second working gas or fluid, at atmospheric pressure or at slight underpressure.

21. The method as defined by claim 20, wherein the first working gas is argon, nitrogen, hydrogen, oxygen, or one of the combinations thereof; and that the second working gas or fluid is a silicon-containing monomer for a deposition of silicon oxide layers, or a carbon-containing monomer for a deposition of carbon layers, on the surface to be treated.

22. The method as defined by claim 16, further comprising the step of cross-linking a silicone layer.

23. An apparatus for performing a method as defined by claim 61, wherein a plasma source is be introduced into an interior of the container or object during the one method step and the further method step, as a coating for the surface treatment; and that means for feeding in the first and the second working gas or fluid are present.

24. An apparatus for performing a method as defined by claim 16, wherein a plasma source is provided on an outside on the container or object during the one method step and the further method step, as a coating for the surface treatment; and that means for feeding in the first and the second working gas or fluid are present.

25. The apparatus as defined by claim 23, wherein the plasma source is an arrangement for generating high-frequency vibration.

26. The apparatus as defined by claim 24, wherein the plasma source is an arrangement for generating high-frequency vibration.

27. The apparatus as defined by claim 24, wherein the plasma source is a microplasma source for inductive, capacitive, or microwave-based power inputting, which can be guided into an interior of the containers or objects to be treated by guide means.

28. The apparatus as defined by claim 27, wherein the microplasma source is used in conjunction with an electron beam source.

29. The apparatus as defined by claim 23, wherein the plasma source is an arrangement disposed outside the containers or objects, for inductive, capacitive, or microwave-based power inputting.

30. The apparatus as defined by claim 24, wherein the plasma source is an arrangement disposed outside the containers or objects, for inductive, capacitive, or microwave-based power inputting.

31. The apparatus as defined by claim 25, wherein the plasma source is an arrangement disposed outside the containers or objects, for inductive, capacitive, or microwave-based power inputting.

32. The apparatus as defined by claim 24, wherein the plasma, in all the method steps, is generated outside the containers or objects to be treated, and can is introduced into one or more containers or objects by means of an arrangement for generating a gas flow.

33. The apparatus as defined by claim 23, wherein the containers or objects are made of plastic.

34. The apparatus as defined by claim 24, wherein the containers or objects are made of plastic.

35. The apparatus as defined by claim 23, wherein the plasma source is coupled to a force measurement cell, on the object that touches a treated surface.
